(19) United States
(12) Patent Application Publication
(10) Pub. No.: US 2026/0080145 A1
(43) Pub. Date: Mar. 19, 2026

(54) DIVIDING DIGITAL CIRCUITS FOR PARALLEL FABRICATION

(71) Applicant: INTERNATIONAL BUSINESS MACHINES CORPORATION, Armonk, NY (US)

(72) Inventors: Mauro Marzorati, Lutz, FL (US); Jeremy Ray Fox, Georgetown, TX (US); Tushar Agrawal, West Fargo, ND (US); Sarbajit Kumar Rakshit, Kolkata (IN)

(21) Appl. No.: 18/887,604

(22) Filed: Sep. 17, 2024

(51) Int. Cl. G06F 30/394

(52) U.S. Cl. CPC G06F 30/394

(57) ABSTRACT

Methods and systems for fabricating a circuit include determining boundaries to divide an original circuit into portions based on resulting portion size and a number of wires crossed by the boundaries. The portions are assigned to respective printers in accordance with the dimensions of the portions and the capabilities of the printers. The portions are fabricated using the assigned printers. A finished circuit is assembled by forming connections between the portions to connect wires broken by the boundaries.

### BACKGROUND

The present invention generally relates to printed circuit fabrication and, more particularly, to the division of an original circuit design into multiple portions.

Modern circuit fabrication makes use of machines that automatically create printed circuit boards according to a circuit design. When manufacturing at large scale, multiple such machines may be operated in parallel to improve the total production capacity. However, each machine may have limitations on the size and type of circuit board that it can handle, and some designs may exceed those limitations. Thus a given design may only be printed on a subset of the machines that are available, for example due to its size. This limits the potential production capacity for such designs.

### SUMMARY

A method for fabricating a circuit includes determining boundaries to divide an original circuit into portions based on resulting portion size and a number of wires crossed by the boundaries. The portions are assigned to respective printers in accordance with the dimensions of the portions and the capabilities of the printers. The portions are fabricated using the assigned printers. A finished circuit is assembled by forming connections between the portions to connect wires broken by the boundaries.

A computer program product includes one or more computer-readable storage media and program instructions stored on the one or more storage media to perform operations. The operations include determining boundaries to divide an original circuit into a plurality of portions based on resulting portion size and a number of wires crossed by the boundaries, assigning the plurality of portions to respective printers in accordance with the dimensions of the plurality of portions and the capabilities of the printers, and triggering fabrication of the plurality of portions using the assigned printers.

A computer system for fabricating a circuit includes a processor set, one or more computer-readable storage media, and program instructions stored on the one or more storage media to cause the processor set to perform operations. The operations include determining boundaries to divide an original circuit into a plurality of portions based on resulting portion size and a number of wires crossed by the boundaries, assigning the plurality of portions to respective printers in accordance with the dimensions of the plurality of portions and the capabilities of the printers, and fabricating the plurality of portions using the assigned printers.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a diagram illustrating how boundaries may be selected to divide an original circuit design into multiple portions that may be fabricated separately in different respective printers, in accordance with an embodiment of the present invention;

FIG. 2 is a block/flow diagram of a method for dividing an original circuit design into multiple portions, fabricating them in different respective printers, and assembling them into a finished device;

FIG. 3 is a block/flow diagram of a method for determining the boundaries between portions of an original circuit design to divide the original circuit into multiple portions, in accordance with an embodiment of the present invention;

FIG. 4 is a diagram illustrating how boundaries may be added to an original circuit design in combination with one another, in accordance with an embodiment of the present invention; and

FIG. 5 is a block diagram of a computing environment that can perform circuit design division, in accordance with an embodiment of the present invention.

### DETAILED DESCRIPTION

Designs for printed circuit board (PCB) fabrication may be divided into multiple portions, with each portion being manufactured separately. The portions may then be connected together, for example by soldering bridges or wires at points where a given wire crosses a board boundary, thereby creating the circuit from multiple PCB portions. A given PCB design may be automatically divided into portions according to boundaries that minimize a number of wire crossings while maximizing portion size. The different portions can then be assigned to different machines for fabrication in accordance with the limitations of those devices.

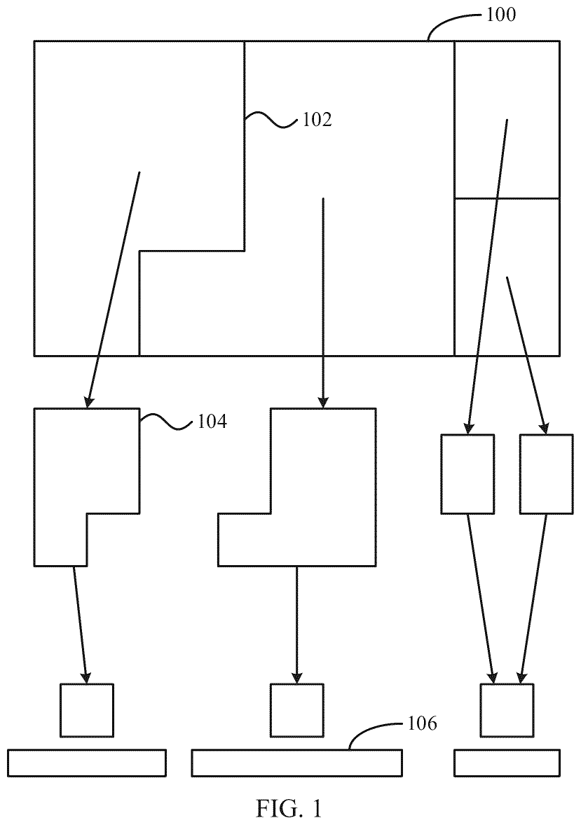

Referring now to FIG. 1, the division of a circuit design into multiple portions for parallel fabrication is shown. An original circuit design 100 is shown. Boundaries 102 may be automatically determined within the original circuit design 100 according to an optimization process, for example by maximizing the size of the portions and minimizing a number of line crossings. The original circuit design 100 may thereby be divided into portions 104 along the boundaries 102. The original circuit 100 may be divided into any appropriate number of portions 104, though fewer portions 104 will make assembly of the final device simpler, as fewer connections will be needed where wires are cut by a boundary 102.

Each of the portions 104 may be fabricated separately, in serial or in parallel. For example, the portions 104 may be assigned to different respective printers 106 for fabrication. It is specifically contemplated that the printers 106 may include three-dimensional (3D) circuit board printers, but it should be understood that any appropriate fabrication device or process may be used instead. In some cases, the printers 106 may have different capacities, for example determined by bed size, which limit the size or other properties of the portions 104 that can be fabricated. A printer 106 with a relatively large capacity can fabricate a relatively small portion 104, but would not be capable of fabricating a portion 104 that has a size exceeding its capacity in some dimension. In some cases, the size of the portions 104 may be measured according to a largest linear dimension. Thus, a square portion 104 may be regarded as smaller than a rectangular portion 104 that has a lower overall area but that is wider.

In some cases, a given printer 106 may fabricate multiple parts 104. In some cases, a single printer 106 may fabricate every portion 104 of a given original circuit design 100. In this manner a relatively small printer 106 can be used to fabricate an original circuit design 100 that exceeds its capacity by breaking the original circuit design 100 into portions 104 that each fit within the limitations of the printer 106.

In some cases the original circuit design 100 may be for a 3D or 2.5D integrated circuit, with multiple PCBs being mounted on one another, with boundaries 102 being available across three dimensions. For example, the original circuit design 100 may include a multi-layer PCB, with vias that penetrate through the layers being analogous to horizontal interconnect wires in a two-dimensional PCB design. Splitting such a 3D design may thus split a 3D PCB into multiple PCBs that can be mounted in a 2.5D package by, e.g., mounting one onto another using solder bumps. In such embodiments, the boundary 102 may split a via along the depth of the original circuit design 100 just as a boundary 102 may split a wire in a cut along the width or length of the original circuit design 100. Splitting a 3D design into multiple layers may be beneficial when some of the available printers 106 lack the ability to print 3D PCBs.

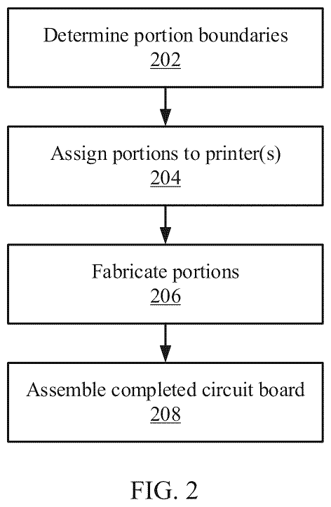

Referring now to FIG. 2, a method for fabricating a circuit board is shown. Block 202 determines boundaries 102 between portions 104 of an original circuit design 100. The boundaries 102 may be determined according to any appropriate optimization objectives, such as minimizing a number of lines that cross the boundaries 102 and maximizing portion size. This determination may further include constraints dictated by the capabilities of the printers 106, for example ensuring that no portion 104 exceeds the capabilities of the largest printer 106. The boundaries 102 may be determined using a linear approach with an objective function on two axes, including wire crossings and portion size.

The analysis of block 202 may include performing trials with different numbers of boundaries 102. All x- and y-values for a given number of boundaries may be evaluated for the number of wire crossings that each set includes. An additional may be added and the evaluation may be repeated. In some cases the boundaries may also be evaluated for whether they cut through a mounted component, with such outcomes being excluded. For example, a component may be an integrated chip, a transistor, a resistor, a capacitor, and inductor, or any other discrete circuit component that may be mounted to a PCB. In some cases the constraint may further exclude boundaries that cut through features of the PCB such as vias or antennas formed in wire traces.

In some cases, the portions 104 may be modified to add connectors. For example, when a given boundary 102 cuts through a wire, a connector may be added on each side of the boundary to connect the wire together during assembly. In some cases multiple wires may be rerouted to a shared connector site, so that a boundary which cuts through multiple wires may have a single connector site, or a set of connector sites smaller than the number of cut wires.

Block 204 then assigns the portions 104 to the printers 106 in accordance with the capacities of the printers 106. In some cases this assignment may be dictated solely by the capacity of a printer 106, for example when only one of the printers 106 has a capacity sufficient to fabricate one or more of the portions 104. In some cases this assignment may be dictated by load balancing, so that the fabrication task is evenly distributed across the printers 106. In some cases, multiple portions 104 may be assigned to a single printer 106.

Block 206 fabricates the portions 104 of the original circuit design 100 using the assigned printers 106. In some cases a given printer 106 may print a single portion 104, while in some cases a given printer 106 may print multiple portions 104. Once the portions 104 have been fabricated, they may be assembled together in block 208 by electrically connecting the portions 104 at points where a line was broken by a boundary. In some cases, the printed portions may include printed indications to aid in assembly, for example adding index numbers that can be matched between the printed portions for soldering connections. In some cases, a computer system may automatically trigger the fabrication 206 after dividing the original circuit design 100 into portions in block 202 and assigning the portions 104 to printers 106 in block 204.

The assembly of block 208 may then be performed manually by a human operator, or may be performed automatically by a system that adds interconnects in the designated places. In embodiments where connectors are added at the boundaries 102, the assembly 208 may include connecting together the connectors on respective sides of a given boundary.

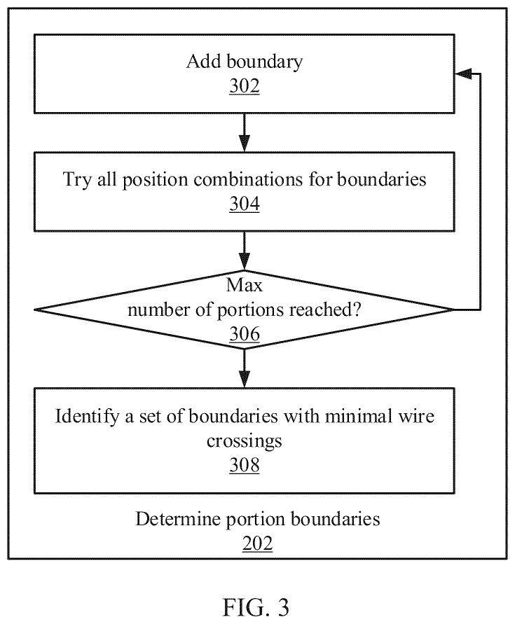

Referring now to FIG. 3, additional detail is shown on determining portion boundaries 202. Block 302 begins by adding a boundary to the original circuit design 100. The boundary may be vertical or horizontal and may initially be placed at an initial position. Block 304 then tries different position combinations for the boundary, tracking the number of times the boundary crosses a wire or circuit component. The boundary may be checked at every possible position on the original circuit design 100, for example using a predetermined step-size or a minimum feature size defined by a printing process to separate one boundary position from the next. Block 306 determines whether a maximum number of portions has been reached. Alternatively, any appropriate stopping condition may be used instead.

If processing continues, then block 302 adds a new boundary. The new boundary may cross one or more previous boundaries, may run parallel to a previous boundary, or may terminate at a previous boundary. Different combinations of boundary types (e.g., crossing vs. terminating) and orientations may be tried in block 304.

Once the different combinations and positions of the boundaries have been exhausted, block 308 identifies a best set of boundaries. The best set of boundaries is selected according to an objective function that balances different goals, such as minimizing the number of wire crossings and maximizing the size of the portions. If there are multiple boundary sets that are equivalent according to the objective function, a heuristic may be used to select which to use, for example based on a number of portions, portion size, or any other appropriate measure. Constraints may furthermore be applied to eliminate certain boundary sets, such as a constraint that ensures no boundary crosses a circuit component. A simplex approach may be used to solve the linear programming optimization.

In one example, the objective function may be expressed as:

$$f ( x , y ) = A \cdot C ( x , y ) - B \cdot S ( x , y )$$

where C(x, y) represents a number of wire crossings at boundaries x and y, S(x, y) represents a size of a portion generated by the boundaries x and y, and A and B are weighting factors that control the tradeoff between minimizing wire crossings and maximizing portion size. This objective function may be minimized subject to certain constraints, such as:

$$S ( x , y ) \leq Max PrinterSize$$

which reflects printing capacity of the printers, and a constraint that dictates no boundary should cross critical circuit components or features like mounted components or vias. It should be understood that this objective function is included purely for illustration and should not be regarded as limiting. Any appropriate objective function may be used to capture other priorities and constraints.

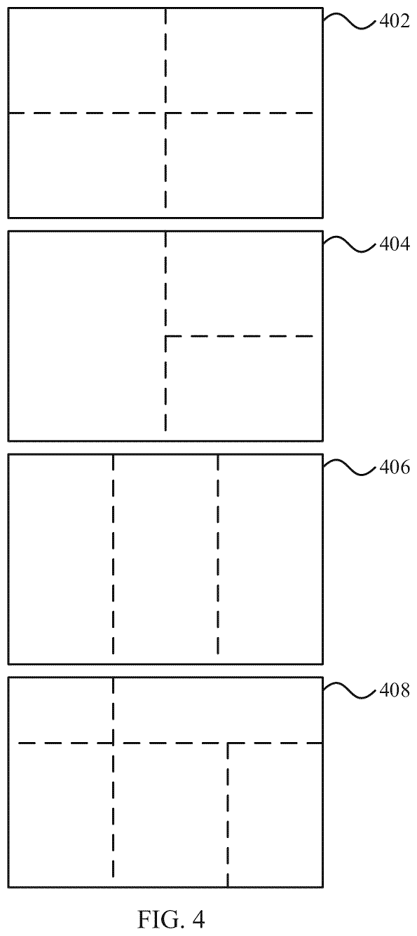

Referring now to FIG. 4, different combinations of boundaries are shown for a given circuit design. In a first example 402, boundaries are shown being perpendicular to one another and crossing. In a second example 404, the boundaries are again perpendicular to one another, but the horizontal boundary terminates at the vertical boundary, so that the portion to the left of the vertical boundary is not divided. In a third example 406, the boundaries are parallel to one another. Any number of such boundaries, in any appropriate combinations, may be evaluated. A fourth example 408 shows a combination of these different relationships between boundaries.

Although the boundaries are shown herein as being straight lines, and generally at right angles to straight-edged borders of the circuit design, it should be understood that the boundaries may take any contour and need not form right angles with respect to one another or to the borders. Thus the portions defined by the boundaries may be generally rectilinear, as shown herein, but may alternatively be defined with irregular edges.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 500 contains an example of an environment for the execution of at least some of the computer code involved in performing the inventive methods, such as circuit design division 519. In addition to block 519, computing environment 500 includes, for example, computer 501, wide area network (WAN) 502, end user device (EUD) 503, remote server 504, public cloud 505, and private cloud 506. In this embodiment, computer 501 includes processor set 510 (including processing circuitry 520 and cache 521), communication fabric 511, volatile memory 512, persistent storage 513 (including operating system 522 and block 519, as identified above), peripheral device set 514 (including user interface (UI) device set 523, storage 524, and Internet of Things (IoT) sensor set 525), and network module 515. Remote server 504 includes remote database 530. Public cloud 505 includes gateway 540, cloud orchestration module 541, host physical machine set 542, virtual machine set 543, and container set 544.

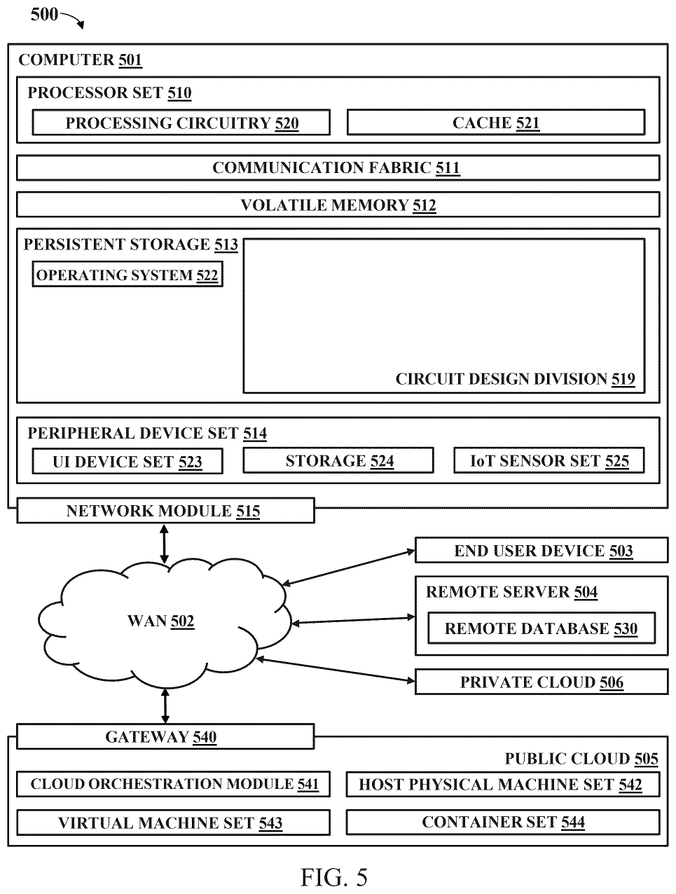

COMPUTER 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 530. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically computer 501, to keep the presentation as simple as possible. Computer 501 may be located in a cloud, even though it is not shown in a cloud in FIG. 5. On the other hand, computer 501 is not required to be in a cloud except to any extent as may be affirmatively indicated.

PROCESSOR SET 510 includes one, or more, computer processors of any type now known or to be developed in the future. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processor set 510. Cache memories are typically organized into multiple levels depending upon relative proximity to the processing circuitry. Alternatively, some, or all, of the cache for the processor set may be located “off chip.” In some computing environments, processor set 510 may be designed for working with qubits and performing quantum computing.

Computer readable program instructions are typically loaded onto computer 501 to cause a series of operational steps to be performed by processor set 510 of computer 501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 521 and the other storage media discussed below. The program instructions, and associated data, are accessed by processor set 510 to control and direct performance of the inventive methods. In computing environment 500, at least some of the instructions for performing the inventive methods may be stored in block 519 in persistent storage 513.

COMMUNICATION FABRIC 511 is the signal conduction path that allows the various components of computer 501 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 512 is any type of volatile memory now known or to be developed in the future. Examples include dynamic type random access memory (RAM) or static type RAM. Typically, volatile memory 512 is characterized by random access, but this is not required unless affirmatively indicated. In computer 501, the volatile memory 512 is located in a single package and is internal to computer 501, but, alternatively or additionally, the volatile memory may be distributed over multiple packages and/or located externally with respect to computer 501.

PERSISTENT STORAGE 513 is any form of non-volatile storage for computers that is now known or to be developed in the future. The non-volatility of this storage means that the stored data is maintained regardless of whether power is being supplied to computer 501 and/or directly to persistent storage 513. Persistent storage 513 may be a read only memory (ROM), but typically at least a portion of the persistent storage allows writing of data, deletion of data and re-writing of data. Some familiar forms of persistent storage include magnetic disks and solid state storage devices. Operating system 522 may take several forms, such as various known proprietary operating systems or open source Portable Operating System Interface-type operating systems that employ a kernel. The code included in block 519 typically includes at least some of the computer code involved in performing the inventive methods.

PERIPHERAL DEVICE SET 514 includes the set of peripheral devices of computer 501. Data communication connections between the peripheral devices and the other components of computer 501 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 523 may include components such as a display screen, speaker, microphone, wearable devices (such as goggles and smart watches), keyboard, mouse, printer, touchpad, game controllers, and haptic devices. Storage 524 is external storage, such as an external hard drive, or insertable storage, such as an SD card. Storage 524 may be persistent and/or volatile. In some embodiments, storage 524 may take the form of a quantum computing storage device for storing data in the form of qubits. In embodiments where computer 501 is required to have a large amount of storage (for example, where computer 501 locally stores and manages a large database) then this storage may be provided by peripheral storage devices designed for storing very large amounts of data, such as a storage area network (SAN) that is shared by multiple, geographically distributed computers. IoT sensor set 525 is made up of sensors that can be used in Internet of Things applications. For example, one sensor may be a thermometer and another sensor may be a motion detector.

NETWORK MODULE 515 is the collection of computer software, hardware, and firmware that allows computer 501 to communicate with other computers through WAN 502. Network module 515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 515 are performed on the same physical hardware device. In other embodiments (for example, embodiments that utilize software-defined networking (SDN)), the control functions and the forwarding functions of network module 515 are performed on physically separate devices, such that the control functions manage several different network hardware devices. Computer readable program instructions for performing the inventive methods can typically be downloaded to computer 501 from an external computer or external storage device through a network adapter card or network interface included in network module 515. WAN 502 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 503 is any computer system that is used and controlled by an end user (for example, a customer of an enterprise that operates computer 501), and may take any of the forms discussed above in connection with computer 501. EUD 503 typically receives helpful and useful data from the operations of computer 501. For example, in a hypothetical case where computer 501 is designed to provide a recommendation to an end user, this recommendation would typically be communicated from network module 515 of computer 501 through WAN 502 to EUD 503. In this way, EUD 503 can display, or otherwise present, the recommendation to an end user. In some embodiments, EUD 503 may be a client device, such as thin client, heavy client, mainframe computer, desktop computer and so on.

REMOTE SERVER 504 is any computer system that serves at least some data and/or functionality to computer 501. Remote server 504 may be controlled and used by the same entity that operates computer 501. Remote server 504 represents the machine(s) that collect and store helpful and useful data for use by other computers, such as computer 501. For example, in a hypothetical case where computer 501 is designed and programmed to provide a recommendation based on historical data, then this historical data may be provided to computer 501 from remote database 530 of remote server 504.

PUBLIC CLOUD 505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 505 is performed by the computer hardware and/or software of cloud orchestration module 541. The computing resources provided by public cloud 505 are typically implemented by virtual computing environments that run on various computers making up the computers of host physical machine set 542, which is the universe of physical computers in and/or available to public cloud 505. The virtual computing environments (VCEs) typically take the form of virtual machines from virtual machine set 543 and/or containers from container set 544. It is understood that these VCEs may be stored as images and may be transferred among and between the various physical machine hosts, either as images or after instantiation of the VCE. Cloud orchestration module 541 manages the transfer and storage of images, deploys new instantiations of VCEs and manages active instantiations of VCE deployments. Gateway 540 is the collection of computer software, hardware, and firmware that allows public cloud 505 to communicate through WAN 502. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 506 is similar to public cloud 505, except that the computing resources are only available for use by a single enterprise. While private cloud 506 is depicted as being in communication with WAN 502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 505 and private cloud 506 are both part of a larger hybrid cloud.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of dividing digital circuits for parallel fabrication (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for fabricating a circuit, comprising:
determining boundaries to divide an original circuit into a plurality of portions based on resulting portion size and a number of wires crossed by the boundaries;
assigning the plurality of portions to respective printers in accordance with dimensions of the plurality of portions and capabilities of the printers;
fabricating the plurality of portions using the assigned printers; and
assembling a finished circuit by forming connections between the plurality of portions to connect wires broken by the boundaries.

2. The method of claim 1, wherein determining the boundaries includes selecting a boundary set based on an objective function that minimizes the number of wires crossed by the boundaries and that maximizes portion size.

3. The method of claim 2, wherein selecting the boundary set further includes applying a constraint to exclude boundary sets that violate the constraint.

4. The method of claim 3, wherein the constraint sets a limit to maximum portion size based on maximum capacity of the printers.

5. The method of claim 3, wherein the constraint excludes boundary sets that include a boundary that crosses a circuit component of the original circuit.

6. The method of claim 3, wherein the constraint excludes boundary sets that include a boundary that crosses a via or an antenna formed from a wire trace.

7. The method of claim 1, wherein the plurality of portions include at least one irregular edge.

8. The method of claim 1, wherein the printers have diverse maximum dimensions for designs that they can fabricate.

9. The method of claim 1, wherein the original circuit is a three-dimensional circuit, the boundaries include at least one boundary along a depth of the three-dimensional circuit, and the wires crossed by the boundaries include at least one via.

10. The method of claim 9, wherein assembling the finished circuit includes mounting at least one of the plurality of portions onto another of the plurality of portions to connect the via using a solder bump.

11. A computer program product, comprising:
one or more computer-readable storage media; and
program instructions stored on the one or more storage media to perform operations, comprising:
determining boundaries to divide an original circuit into a plurality of portions based on resulting portion size and a number of wires crossed by the boundaries;
assigning the plurality of portions to respective printers in accordance with dimensions of the plurality of portions and capabilities of the printers; and
triggering fabrication of the plurality of portions using the assigned printers.

12. A computer system for fabricating a circuit, comprising:
a processor set;
one or more computer-readable storage media; and
program instructions stored on the one or more storage media to cause the processor set to perform operations, comprising:
determining boundaries to divide an original circuit into a plurality of portions based on resulting portion size and a number of wires crossed by the boundaries;
assigning the plurality of portions to respective printers in accordance with dimensions of the plurality of portions and capabilities of the printers; and
fabricating the plurality of portions using the assigned printers.

13. The system of claim 12, wherein determining the boundaries includes selecting a boundary set based on an objective function that minimizes the number of wires crossed by the boundaries and that maximizes portion size.

14. The system of claim 13, wherein selecting the boundary set further includes applying a constraint to exclude boundary sets that violate the constraint.

15. The system of claim 14, wherein the constraint sets a limit to maximum portion size based on maximum capacity of the printers.

16. The system of claim 14, wherein the constraint excludes boundary sets that include a boundary that crosses a circuit component of the original circuit.

17. The system of claim 14, wherein the constraint excludes boundary sets that include a boundary that crosses a via or an antenna formed from a wire trace.

18. The system of claim 12, wherein the plurality of portions include at least one irregular edge.

19. The system of claim 12, wherein the printers have diverse maximum dimensions for designs that they can fabricate.

20. The system of claim 12, wherein the original circuit is a three-dimensional circuit, the boundaries include at least one boundary along a depth of the three-dimensional circuit, and the wires crossed by the boundaries include at least one via.
